(19) United States
(12) Patent Application Publication
(10) Pub. No.: US 2026/0123358 A1
(43) Pub. Date: Apr. 30, 2026

(54) DISPLAY DEVICE, DEVICE FOR INSPECTING DISPLAY DEVICE, METHOD FOR INSPECTING OF DISPLAY DEVICE USING THE DEVICE, AND ELECTRONIC DEVICE

(71) Applicant: Samsung Display Co., LTD., Yongin-si (KR)

(72) Inventor: Je Hyeon YOON, Yongin-si (KR)

(21) Appl. No.: 19/283,745

(22) Filed: Jul. 29, 2025

(30) Foreign Application Priority Data
Oct. 31, 2024 (KR) 10-2024-0152379

(51) Int. Cl. H01L 21/66; H10H 29/01; H10H 29/34

(52) U.S. Cl. CPC H10P 74/203; H10H 29/012; H10H 29/34

(57) ABSTRACT

A display device, an inspection device, a method for inspecting a display device, and an electronic device are provided. The display device includes a substrate including a display area and a non-display area, a plurality of light emitting elements disposed in a plurality of columns and a plurality of rows in the display area, a plurality of first row imitation patterns disposed in the same column as the light emitting elements of the first row in the non-display area and a plurality of first column imitation patterns disposed in the same row as the light emitting elements of the first column in the non-display area, wherein each of the plurality of first row imitation patterns has the same shape and the same area as the light emitting elements disposed in the same column among the light emitting elements of the first row.

This application claims priority to Korean Patent Application No. 10-2024-0152379, filed on Oct. 31, 2024, and all the benefits accruing therefrom under 35 U.S.C. § 119, the content of which in its entirety is herein incorporated by reference.

### BACKGROUND

### 1. Field

The present disclosure relates to a display device, an inspection device, a method for inspecting a display device, and an electronic device.

### 2. Description of the Related Art

As the information society develops, the demand for display devices for displaying images is increasing in various forms. The display device may be a flat panel display device such as, for example, a liquid crystal display, a field emission display, a light emitting display, or the like.

The light emitting display device may be implemented as an organic light emitting display device including an organic light emitting diode (OLED) element as a light emitting element, an inorganic light emitting display device including an inorganic semiconductor element as a light emitting element, or an ultra-small light emitting diode display device including an ultra-small light emitting diode element (or micro light emitting diode element) as a light emitting element.

### SUMMARY

Aspects and features of embodiments of the present disclosure are to provide a display device, an inspection device, and a display device inspection method for detecting detachment and misalignment of a light emitting element.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a display device includes a substrate including a display area and a non-display area, a plurality of light emitting elements disposed in a plurality of columns and a plurality of rows in the display area, a plurality of first row similar patterns disposed in the same column as the light emitting elements of the first row in the non-display area and a plurality of first column similar patterns disposed in the same row as the light emitting elements of the first column in the non-display area, wherein each of the plurality of first row similar patterns has the same shape and the same area as the light emitting elements disposed in the same column among the light emitting elements of the first row.

According to an embodiment, wherein the plurality of similar patterns of the first column and the plurality of similar patterns of the first row are formed of metal, wherein the light emitting element is a light emitting element made of an inorganic material.

According to an embodiment, wherein the plurality of similar patterns of the first row are disposed at the top or bottom of the display area, wherein the plurality of similar patterns of the first column are disposed at the left or right of the display area.

According to one or more embodiments of the present disclosure, an inspection device includes a stage on which a substrate including a plurality of similar patterns and a plurality of light emitting elements is mounted, an image acquisition portion for photograph an image of the substrate, a control portion for controlling an operation of the image acquisition portion and an image processing portion for comparing image data of similar patterns with image data of light emitting elements through image data obtained from the image acquisition portion to determine whether the light emitting elements are defective.

According to an embodiment, wherein the substrate includes a display area and a non-display area, wherein the plurality of light emitting elements are disposed in a plurality of columns and a plurality of rows in the display area, and wherein the plurality of similar patterns include a plurality of similar patterns of a first row disposed in the same column as the light emitting elements of the first row in the non-display area and a plurality of similar patterns of a first column disposed in the same row as the light emitting elements of the first column.

According to an embodiment, wherein the presence of a defect includes a detachment or misalignment of the light emitting elements from their proper positions.

According to an embodiment, wherein the image processing portion detects the detachment and misalignment of the light emitting elements by using a difference between the gray value of the light emitting element and the gray values of the plurality of similar patterns of the first row corresponding to the light emitting element and the corresponding similar patterns of the first column.

According to an embodiment, wherein the image processing portion extracts image data of similar patterns corresponding to the light emitting element to be detected based on the previously stored similar patterns and the position data of the light emitting elements.

According to an embodiment, wherein the plurality of similar patterns of the first row have the same shape and the same area as the light emitting element of the first column.

According to an embodiment, wherein the plurality of similar patterns of the first column and the plurality of similar patterns of the first row are formed of metal, wherein the light emitting element is made of an inorganic material.

According to an embodiment, wherein the plurality of similar patterns of the first row are disposed at a top or bottom of the display area, and wherein the plurality of similar patterns of the first column are disposed at the left or right of the display area.

According to an embodiment, the inspection device further includes an output portion that receives a defect inspection result from the image processing portion and displays it.

According to one or more embodiments of the present disclosure, a method for inspecting a display device includes placing a target substrate having a plurality of light emitting elements formed on a stage and aligning an image acquisition portion on the target substrate, the allowing the image acquisition portion to photograph an image of the target substrate including the similar patterns and the light emitting elements to acquire a first image and allowing an image processing portion to compare image data of the similar patterns with image data of the light emitting elements through image data obtained from the image acquisition portion to determine whether the light emitting elements are defective.

According to an embodiment, wherein the substrate includes a display area and a non-display area, wherein the plurality of light emitting elements are disposed in a plurality of columns and a plurality of rows in the display area, and wherein the plurality of similar patterns include a plurality of similar patterns of a first row disposed in the same column as the light emitting elements of the first row in the non-display area and a plurality of similar patterns of a first column disposed in the same row as the light emitting elements of the first column.

According to an embodiment, the determining whether a defect is present is, wherein the image processing portion extracts image data of the similar patterns corresponding to the light emitting element to be detected based on the previously stored similar patterns and the position data of the light emitting elements.

According to an embodiment, wherein the image processing portion determines a defect if the similarity between the image data of the image data of the light emitting element to be inspected and the corresponding similar patterns is less than a preset reference value.

According to an embodiment, wherein the image data is luminance data.

According to an embodiment, wherein the image processing portion determines the detachment and misalignment of the light emitting elements by using a difference between a gray value of the light emitting element and the gray values of the plurality of similar patterns of the first row corresponding to the light emitting element and the corresponding similar patterns of the first column.

According to an embodiment, wherein the image processing portion determines the detachment and misalignment of the light emitting elements by using a difference between a gray value of the light emitting element and the gray values of the plurality of similar patterns of the first row corresponding to the light emitting element and the corresponding similar patterns of the first column.

According to an embodiment, wherein the plurality of similar patterns of the first row have the same shape and the same area as the light emitting elements of the first column, wherein the plurality of similar patterns of the first row are disposed at a top or bottom of the display area, and wherein the plurality of similar patterns of the first column are disposed at the left or right of the display area.

According to one or more embodiments of the present disclosure, An electronic device includes a display device for displaying an image, wherein the display device includes, a substrate including a display area and a non-display area, a plurality of light emitting elements disposed in a plurality of columns and a plurality of rows in the display area, a plurality of first row similar patterns disposed in the same column as the light emitting elements of the first row in the non-display area and a plurality of first column similar patterns disposed in the same row as the light emitting elements of the first column in the non-display area, wherein each of the plurality of first row similar patterns has the same shape and the same area as the light emitting elements disposed in the same column among the light emitting elements of the first row.

According to an embodiment, the position of a defective light emitting element may be accurately identified using a similar pattern of a substrate.

In addition, according to an embodiment, detachment and misalignment of a light emitting substrate may be identified.

However, the effects of the present disclosure are not limited to the aforementioned effects, and various other effects are included in the present specification.

### BRIEF DESCRIPTION OF THE DRAWINGS

FIG. 1 is a perspective view illustrating a display device according to an embodiment.

FIG. 2 is a layout drawing illustrating a display device according to an embodiment.

FIG. 3 is a block drawing illustrating a display device according to an embodiment.

FIG. 4 is an equivalent circuit drawing illustrating a sub-pixel according to an embodiment.

FIG. 5 is a layout drawing illustrating pixels of a display area according to an embodiment.

FIG. 6 is a cross-sectional view illustrating one example of a cross-section of a display panel corresponding to line I-I′ in FIG. 5.

FIG. 7 is a cross-sectional view illustrating one example of area A of FIG. 6 in detail.

FIG. 8 is an enlarged view of a portion of a display device to illustrate an imitation pattern and an array of light emitting elements.

FIG. 9 is a block diagram schematically illustrating an inspection device according to an embodiment.

FIG. 10 is a flowchart illustrating an inspection method of a display device according to an embodiment.

FIG. 11 is a schematic diagram to illustrate an inspection method of a display device according to an embodiment.

FIG. 12 is an example of position data according to an embodiment.

FIG. 13 and FIG. 14 are images for detecting a defect in a light emitting element by comparing one pixel to an imitation pattern.

FIG. 15 is an image for illustrating defect detection in a conventional light emitting element.

FIG. 16 to FIG. 18 are drawings to illustrate types of misalignment defects of light emitting elements that may be detected according to an embodiment of the present disclosure.

FIG. 19 is an example view of a smart watch including a display device according to one or more embodiments.

FIGS. 20 and 21 are example views of a virtual reality (VR) device including a display device according to one or more embodiments.

FIG. 22 is an example view of a VR device including a display device according to one or more embodiments.

FIG. 23 is an example view illustrating a vehicle instrument cluster and center fascia including display devices according to one or more embodiments.

FIG. 24 is an example view of a transparent display device including a display device according to one or more embodiments.

### DETAILED DESCRIPTION

Aspects and features of embodiments of the present disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, the embodiments are provided as examples such that the present disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure might not be described.

Unless otherwise noted, like reference numerals, characters, or combinations thereof denote like elements throughout the attached drawings and the written description, and thus, descriptions thereof will not be repeated. Further, parts not related to the description of one or more embodiments might not be illustrated to make the description clear.

In the drawings, the relative sizes of elements, layers, and regions may be exaggerated for clarity. The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are illustrative for the purpose of describing embodiments according to the present disclosure. Thus, embodiments disclosed herein should not be construed as limited to the particular illustrated shapes of regions, but are to include deviations in shapes that result from, for instance, manufacturing.

For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. As those skilled in the art would realize, the described embodiments may be modified in various different ways, all without departing from the spirit and/or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are illustrated in block diagram form to avoid unnecessarily obscuring various embodiments.

Spatially relative terms, such as, for example, “beneath,” “below,” “lower,” “under,” “above,” “upper,” and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In an example in which a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. Other expressions describing relationships between components such as, for example, “between,” “immediately between” or “adjacent to” and “directly adjacent to” may be construed similarly. It will also be understood that when an element or layer is referred to as being “between” two elements or layers, it can be the only element or layer between the two elements or layers, or one or more intervening elements or layers may also be present.

For the purposes of the present disclosure, expressions such as, for example, “at least one of,” “one of,” and “selected from,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression “at least one of A and/or B” may include A, B, or A and B. As used herein, the term “and/or” includes any and all combinations of one or more of the associated listed items. For example, the expression “A and/or B” may include A, B, or A and B. Further, the use of “may” when describing embodiments of the present disclosure refers to “one or more embodiments of the present disclosure”.

It will be understood that, although the terms “first,” “second,” “third,” or the like, may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described herein could be termed a second element, component, region, layer or section, without departing from the spirit and scope of the present disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” When one or more embodiments may be implemented differently, a specific process order may be performed differently from the described order. For example, two consecutively described processes may be performed substantially at the same time or performed in an order opposite to the described order.

Any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the present disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. A person of skill in the art should recognize that the functionality of various computing devices may be combined or integrated into a single computing device, or the functionality of a particular computing device may be distributed across one or more other computing devices without departing from the spirit and scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

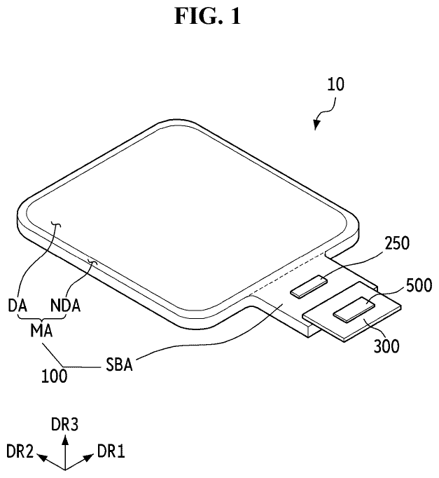

FIG. 1 is a perspective view illustrating a display device according to an embodiment.

Referring to FIG. 1, a display device 10 is a device for displaying video or still images, such as, for example, mobile phones, smart phones, tablet personal computers, and portable electronic devices such as, for example, smart watches, watch phones, mobile communication terminals, electronic notebooks, e-books, portable electronic devices such as, for example, portable multimedia players (PMP), navigation, and ultra mobile PC (UMPC), as well as display screens for a variety of products such as, for example, televisions, laptops, monitors, billboards, and the internet of things (IOT).

The display device 10 may be a light emitting display device, such as, for example, an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light emitting diode (micro LED or nano LED). Hereinafter, the description focuses on the fact that the display device 10 is a micro-light emitting display device, but embodiments of the present disclosure are not limited thereto. In some embodiments, hereinafter, an ultra-small light emitting diode is described as a light emitting element for convenience of explanation.

The display device 10 includes a display panel 100, a display driving circuit 250, a circuit substrate 300, and a power supply circuit 500.

The display panel 100 may be formed as a rectangular shaped plane having a short side in the first direction DR1 and a long side in the second direction DR2 that intersects the first direction DR1. A corner where the short side in the first direction DR1 and the long side in the second direction DR2 meet may be rounded to have a predetermined curvature or may be formed at a right angle. The planar shape of the display panel 100 is not limited to a rectangle, but may be formed in other polygonal, circular, or oval shapes. The display panel 100 may be formed flat but is not limited thereto. In one example, the display panel 100 may be formed at the left and right ends and may include curved portions with a constant curvature or a changing curvature. In some aspects, the display panel 100 may be flexibly formed to be bent, curved, bent, folded, or rolled.

The display panel 100 may include the main area MA and the sub-area SBA.

The main area MA may include a display area DA that displays an image and a non-display area NDA that is a surrounding area of the display area DA. The display area DA may include a plurality of pixels that display an image. Each pixel may include a plurality of sub-pixels. For example, each of the pixels may include a first sub-pixel that emits a first light, a second sub-pixel that emits a second light, and a third sub-pixel that emits a third light, but the embodiments of the present disclosure are not limited thereto.

The sub-area SBA may protrude from one side of the main area MA in the second direction DR2. Although FIG. 1 illustrates the sub-area SBA being unfolded, the sub-area SBA may be bent, and in this case, may be disposed on the lower surface of the display panel 100. In an example in which the sub-area SBA is bent, it may overlap the main area MA in a third direction DR3, which is the thickness direction of the display panel 100. The display driving circuit 250 may be disposed in the sub-area SBA.

The display driving circuit 250 may generate signals and voltages for driving the display panel 100. The display driving circuit 250 may be formed as an integrated circuit (IC) and attached to the display panel 100 using a chip on glass (COG) method, a chip on plastic (COP) method, or an ultrasonic bonding method but is not limited thereto. In an embodiment, the display driving circuit 250 may be attached to the circuit substrate 300 using a chip on film (COF) method.

The circuit substrate 300 may be attached to one end of the sub-area SBA of the display panel 100. As such, the circuit substrate 300 may be electrically connected to the display panel 100 and the display driving circuit 250. The display panel 100 and the display driving circuit 250 may receive digital video data, timing signals, and driving voltages through the circuit substrate 300. The circuit substrate 300 may be a flexible film, such as, for example, a flexible printed circuit substrate, a printed circuit substrate, or a chip on film.

The power supply circuit 500 may generate a plurality of panel driving voltages according to an external power supply voltage. The power supply circuit 500 may be formed as an integrated circuit (IC) and attached to the circuit substrate 300 using a COF method.

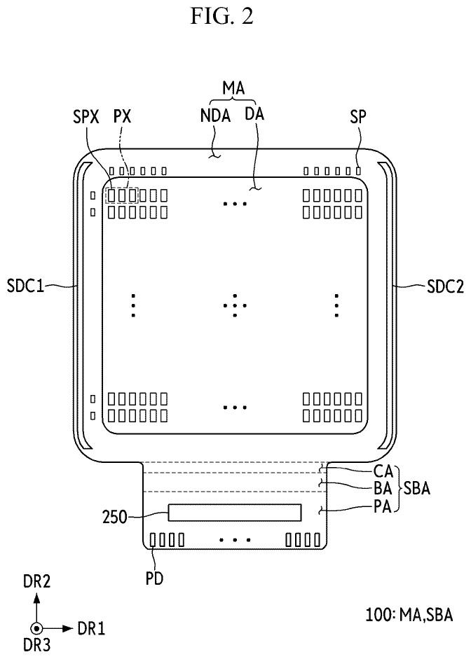

FIG. 2 is a layout drawing illustrating a display device according to an embodiment. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA includes a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be disposed adjacent to the display area DA. The non-display area NDA may be an area outside the display area DA. The non-display area NDA may be arranged to surround the display area DA. The non-display area NDA may be an edge area of the display panel 100.

The non-display area NDA may include an imitation pattern SP that is used as a reference for alignment of the light emitting elements LE when detecting a defect in the light emitting elements LE.

The imitation pattern SP may be disposed on one side (e.g., the left and upper side) of the display panel 100 but is not limited thereto. The imitation pattern SP is aligned with the correct positions of the light emitting elements LE of a plurality of pixels PX in the same row and/or the same column. The imitation pattern SP may be formed of metal and has the same shape and size as the light emitting elements LE of the same row and/or the same column but is not electrically connected to the plurality of pixels PX (light emitting elements LE).

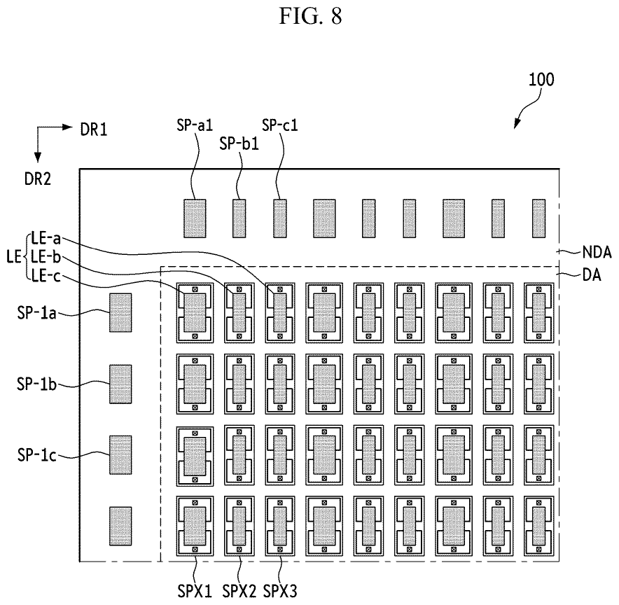

The shape, arrangement, and utilization of the imitation pattern SP will be described in detail with reference to FIG. 8.

In some aspects, a first scan driving portion SDC1 and a second scan driving portion SDC2 may be disposed in the non-display area NDA. The first scan driving portion SDC1 is disposed on one side (e.g., the left side) of the display panel 100, and the second scan driving portion SDC2 is disposed on the other side (e.g., the right side) of the display panel 100 but are not limited thereto. Each of the first scan driving portion SDC1 and the second scan driving portion SDC2 may be electrically connected to the display driving circuit 250 through scan fan out lines. Each of the first scan driving portion SDC1 and the second scan driving portion SDC2 may receive a scan control signal from the display driving circuit 250, generate scan signals according to the scan control signal, and output them to scan lines.

The sub-area SBA may protrude from one side of the main area MA in the second direction DR2. The length of the sub-area SBA in the second direction DR2 may be smaller than the length of the main area MA in the second direction DR2. The length of the first direction DR1 of the sub area SBA may be less than the length of the first direction DR1 of the main area MA or may be substantially equal to the length of the first direction DR1 of the main area MA. The sub-area SBA may be curved and may be disposed at a lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are disposed. The display driving circuit 250 may be attached to the driving pads of the pad area PA using a conductive adhesive member such as, for example, an anisotropic conductive film. The circuit substrate 300 may be attached to the pads PD of the pad area PA using a conductive adhesive member such as, for example, an anisotropic conductive film. One side of the pad area PA may be in contact with the bending area BA.

The bending area BA is a bent area. In an example in which the bending area BA is bent, the pad area PA may be disposed below the connection area CA and below the main area MA. The bending area BA may be disposed between the connection area CA and the pad area PA. One side of the bending area BA may be in contact with the connection area CA, and the other side of the bending area BA may be in contact with the pad area PA.

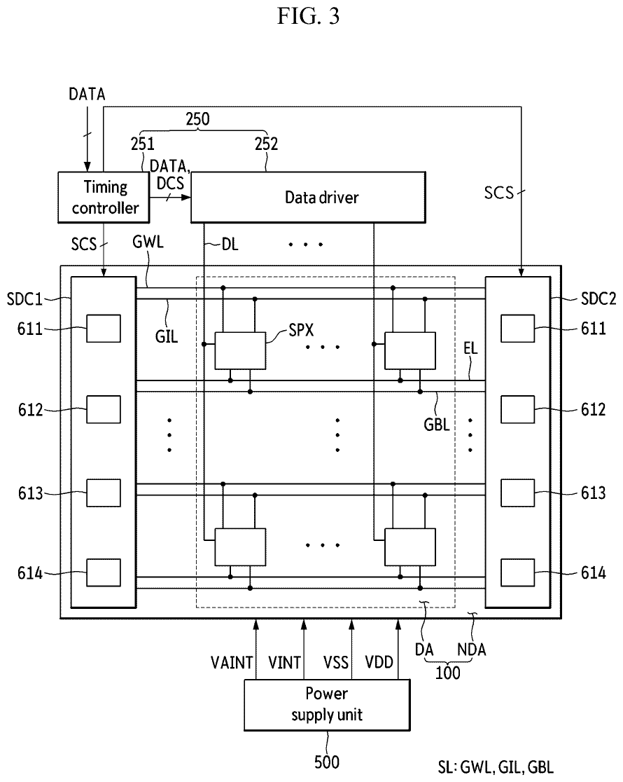

FIG. 3 is a block drawing illustrating a display device according to an embodiment.

Referring to FIG. 3, the display area DA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 and be disposed in the second direction DR2. The plurality of data lines DL may extend in the second direction DR2 and be disposed in the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light emitting elements according to the data voltage.

The non-display area NDA includes a first scan driving portion SDC1, a second scan driving unit SDC2, and a display driving circuit 250.

Each of the first scan driving portion SDC1 and the second scan driving portion SDC2 may include a write scan signal output portion 611, an initialization scan signal output portion 612, a bias scan signal output portion 613, and an emission control signal output portion 614. Each of the write scan signal output portion 611, the initialization scan signal output portion 612, the bias scan signal output portion 613, and the emission control signal output portion 614 may receive a scan timing control signal SCS from a timing control circuit 251.

The write scan signal output portion 611 may generate write scan signals according to the scan timing control signal SCS of the timing control circuit 251 and sequentially output them to the write scan lines GWL.

The initialization scan signal output portion 612 may generate initialization scan signals according to the scan timing control signal SCS and sequentially output them to the initialization scan lines GIL.

The bias scan signal output portion 613 may generate bias scan signals according to the scan timing control signal SCS and sequentially output them to the bias scan lines GBL. The emission control signal output portion 614 may generate emission control signals according to the scan timing control signal SCS and sequentially output them to the emission control lines EL.

The display driving circuit 250 includes a timing control circuit 251 and a data driving circuit 252.

The data driving circuit 252 may receive digital video data DATA and a data timing control signal DCS from the timing control circuit 251. The data driving circuit 252 converts digital video data DATA into analog data voltages according to the data timing control signal DCS and outputs them to the data lines DL. In this case, the sub-pixels SPX are selected by the write scan signals of the first scan driving unit SDC1 and the second scan driving unit SDC2, and data voltages may be supplied to the selected sub-pixels SPX.

The timing control circuit 251 may receive digital video data DATA and timing signals from the outside. The timing control circuit 251 may generate a scan timing control signal SCS and a data timing control signal DCS for controlling the display panel 100 according to the timing signals. The timing control circuit 400 may output the scan timing control signal SCS to the first scan driving portion SDC1 and the second scan driving portion SDC2. The timing control circuit 251 may output digital video data DATA and a data timing control signal DCS to the data driving circuit 252.

The power supply circuit 500 may generate a plurality of panel driving voltages according to a power voltage supplied from the outside. For example, the power supply circuit 500 may generate a first power supply voltage VDD, a second power supply voltage VSS, a third power supply voltage VINT, and a fourth power supply voltage VAINT and supply them to the display panel 100.

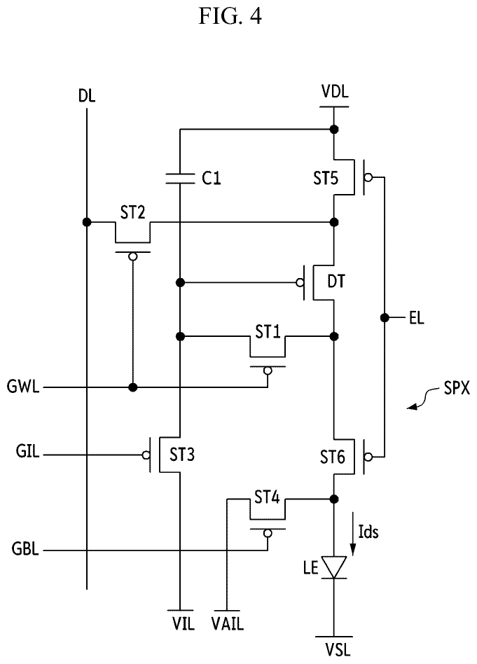

FIG. 4 is an equivalent circuit drawing illustrating a sub-pixel according to an embodiment.

Referring to FIG. 4, a sub-pixel SPX according to an embodiment may be connected to scan lines GWL, GIL, and GBL, an emission control line EL, and a data line DL. For example, the sub-pixel SPX may be connected to a write scan line GWL, an initialization scan line GIL, a bias scan line GBL, an emission control line EL, and a data line DL.

The sub-pixel SPX according to an embodiment includes a driving transistor DT, switching elements, a capacitor C1, and a lighting element LE. The switching elements include first to sixth transistors ST1, ST2, ST3, ST4, ST5, and ST6.

The driving transistor DT includes a gate electrode, a first electrode, and a second electrode. The driving transistor DT controls a drain-source current (Ids, hereinafter referred to as “driving current”) flowing between the first electrode and the second electrode according to a data voltage applied to a gate electrode.

The light emitting element LE1 may be a micro light emitting diode.

The light emitting element LE emits light according to the driving current Ids. The amount of light emitted from the light emitting element LE may be proportional to the driving current Ids. The anode electrode of the light emitting element LE is connected to the first electrode of the fourth transistor ST4 and the second electrode of the sixth transistor ST6, and the cathode electrode may be connected to a second power supply line VSL to which a second power supply voltage is applied.

A capacitor C1 is formed between a gate electrode of a driving transistor DT and a first power supply line VDL to which a first power supply voltage is applied. The first power supply voltage may be a voltage of a higher level than the second power supply voltage. One electrode of the capacitor C1 may be connected to the gate electrode of the driving transistor DT, and the other electrode may be connected to the first power supply line VDL.

As illustrated in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon.

The gate electrode of the first transistor ST1 and the gate electrode of the second transistor ST2 may be connected to the write scan line GWL, and the gate electrode of the third transistor ST3 may be connected to the initialization scan line GIL, and the gate electrode of the fourth transistor ST4 may be connected to the bias scan line GBL. Since the first to sixth transistors ST1, ST2, ST3, ST4, ST5, and ST6 are formed as p-type MOSFET and they may be turned on when a scan signal of a gate low voltage and an emission control signal are applied to the initialization scan line GIL, the write scan line GWL, the bias scan line GBL, and the emission line EL, respectively. One electrode of the third transistor ST3 may be connected to the first initialization voltage line VIL to which the third power supply voltage (VINT of FIG. 3) is applied, and one electrode of the fourth transistor ST4 may be connected to the second initialization voltage line VAIL to which the fourth power supply voltage (VAINT of FIG. 3) is applied. The third power supply voltage (VINT of FIG. 3) and the fourth power supply voltage (VAINT of FIG. 3) may be different voltages. Further, the third power supply voltage (VINT in FIG. 3) and the fourth power supply voltage (VAINT in FIG. 3) may be voltages at a lower level than the first power supply voltage VDD and at a higher level than the second power supply voltage VSS.

Alternatively, the driving transistor DT, the second transistor ST2, the fourth transistor ST4, the fifth transistor ST5, and the sixth transistor ST6 may be formed of a p-type MOSFET, and the first transistor ST1 and the third transistor ST3 may be formed of an n-type MOSFET. In this case, the active layers of each of the driving transistor DT, the second transistor ST2, the fourth transistor ST4, the fifth transistor ST5, and the sixth transistor ST6 formed of p-type MOSFETs are formed of polysilicon, the active layers of each of the first transistor ST1 and the third transistor ST3 formed of an n-type MOSFET may be formed of an oxide semiconductor. Furthermore, since the first transistor ST1 and the third transistor ST3 are formed as n-type MOSFET, the first transistor ST1 may be turned on when a scan signal of the gate high voltage is applied, and the third transistor ST3 may be turned on when an initialization scan signal of the gate high voltage is applied. In contrast, the second transistor ST2, the fourth transistor ST4, the fifth transistor ST5, and the sixth transistor ST6 are formed as p-type MOSFET, so they may be turned on when a scan signal of the gate low voltage and a light emission control signal are applied.

Alternatively, the fourth transistor ST4 may be formed as an n-type MOSFET, and the remaining transistors DT, ST1, ST2, ST3, ST5, and ST6 may be formed as p-type MOSFET, in which case the active layer of the fourth transistor ST4 may be formed as an oxide semiconductor, and the active layers of each of the remaining transistors DT, ST1, ST2, ST3, ST5, and ST6 may be formed as polysilicon. Further, the fourth transistor ST4 may be turned on when a scan signal of a gate high voltage is applied, whereas the remaining transistors DT, ST1, ST2, ST3, ST5, and ST6 may be turned on when a scan signal of a gate low voltage and a light emission control signal are applied.

Alternatively, the first to sixth transistors ST1, ST2, ST3, ST4, ST5, and ST6 and the driving transistor DT may all be formed as n-type MOSFET. In this case, the active layer of each of the first to sixth transistors ST1, ST2, ST3, ST4, ST5, and ST6 and the driving transistor DT is formed of an oxide semiconductor and may be turned on when a scan signal of a gate high voltage and a light emission control signal are applied.

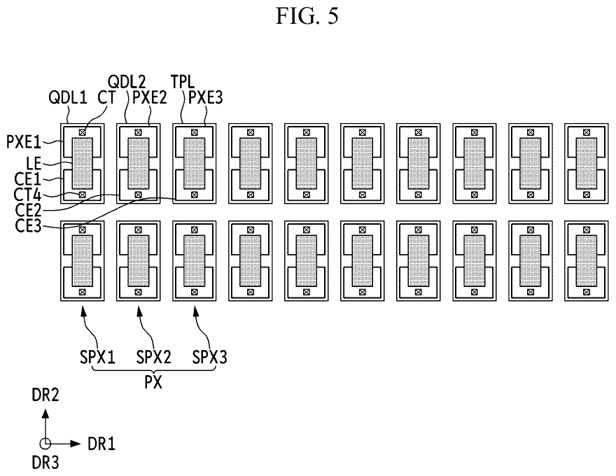

FIG. 5 is a layout drawing illustrating pixels of a display area according to an embodiment.

Referring to FIG. 5, each of the plurality of pixels PX of the display area DA may include three sub-pixels SPX1, SPX2, and SPX3, but embodiments of the present disclosure are not limited thereto and may include four sub-pixels. In an example in which each of the plurality of pixels PX includes three sub-pixels SPX1, SPX2, and SPX3, the first sub-pixel SPX1, the second sub-pixel SPX2, and the third sub-pixel SPX3 may include.

When each of the plurality of pixels PX includes three sub-pixels SPX1, SPX2, and SPX3, the first sub-pixel SPX1 may emit light of a first color, and the second sub-pixel SPX2 may emit light of a second color, and the third sub-pixel SPX3 may emit light of a third color. Here, the first color light may be light in a blue wavelength band, the second color light may be light in a green wavelength band, and the third color light may be light in a red wavelength band. For example, the blue wavelength band may refer to light having a main peak wavelength in the wavelength band from approximately 370 nm to 460 nm, the green wavelength band may refer to light having a main peak wavelength in the wavelength band from approximately 480 nm to 560 nm, and the red wavelength band may refer to light having a main peak wavelength in the wavelength band from approximately 600 nm to 750 nm.

Alternatively, when each of the plurality of pixels PX includes four sub-pixels, the first sub-pixel may emit light of a first color, the second and fourth sub-pixels may emit light of a second color, and the third sub-pixel may emit light of a third color. Alternatively, the first sub-pixel may emit light of a first color, the second sub-pixel may emit light of a second color, the third sub-pixel may emit light of a third color, and the fourth sub-pixel may emit light of a fourth color. In this case, the fourth color light may be white light.

The first sub-pixel SPX1 includes a first pixel electrode PXE1, a plurality of light emitting elements LE, and a first light conversion layer QDL1. The second sub-pixel SPX2 includes a second pixel electrode PXE2, a plurality of light emitting elements LE, and a second light conversion layer QDL2. The third sub-pixel SPX3 includes a third pixel electrode PXE3, a plurality of light-emitting elements LE, and a third light conversion layer QDL3.

In each of the first sub-pixel SPX1, the second sub-pixel SPX2, and the third sub-pixel SPX3, pixel electrodes PXE1, PXE2, and PXE3 and common electrodes CE1, CE2, and CE3 may be disposed in the second direction DR2. Each of the pixel electrodes PXE1, PXE2, and PXE3 and the common electrodes CE1, CE2, and CE3 may have a rectangular plane shape, but embodiments of the present disclosure are not limited thereto. The area of the first pixel electrode PXE1 may be the same as the area of the first common electrode CE1, the area of the second pixel electrode PXE2 may be the same as the area of the second common electrode CE2, and the area of the third pixel electrode PXE3 may be the same as the area of the third common electrode CE3, but embodiments of the present disclosure are not limited thereto.

Each of the pixel electrodes PXE1, PXE2, and PXE3 may be electrically connected to at least one transistor through the pixel connection hole CT1, CT2, and CT3. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may be referred to as an anode electrode or a first electrode, and the common electrodes CE1, CE2, and CE3 may be referred to as a cathode electrode or a second electrode.

A plurality of light emitting elements LE may be disposed on the pixel electrodes PXE1, PXE2, and PXE3 and the common electrode CE1, CE2, and CE3. Each of the plurality of light emitting elements LE may have a rectangular planar shape, but embodiments of the present disclosure are not limited thereto. For example, each of the plurality of light emitting elements LE may have a circular planar shape.

The first light conversion layer QDL1 may completely overlap with the plurality of light emitting elements LE of the first sub-pixel SPX1. The first light conversion layer QDL1 may convert or shift the peak wavelength of incident light into light of another specific peak wavelength and emit the light. For example, the first light conversion layer QDL1 may convert or shift third light emitted from the plurality of light emitting elements LE of the first sub-pixel SPX1 into first light.

The second light conversion layer QDL2 may completely overlap with the plurality of light emitting elements LE of the second sub-pixel SPX2. The area of the second light conversion layer QDL2 may be larger than the area of the second pixel electrode PXE2. The second light conversion layer QDL2 may convert or shift the peak wavelength of incident light into light of another specific peak wavelength and emit the light. For example, the second light conversion layer QDL2 may convert or shift the third light emitted from the plurality of light emitting elements LE of the second sub-pixel SPX2 into the second light.

The light transmission layer TPL may completely overlap the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

When the light emitting element LE of the first sub-pixel SPX1 emits light of a first color, the light emitting element LE of the second sub-pixel SPX2 emits light of a second color, and the light emitting element LE of the third sub-pixel SPX3 emits light of a third color, the light conversion layers QDL1 and QDL2 and the light transmission layer TPL may be omitted.

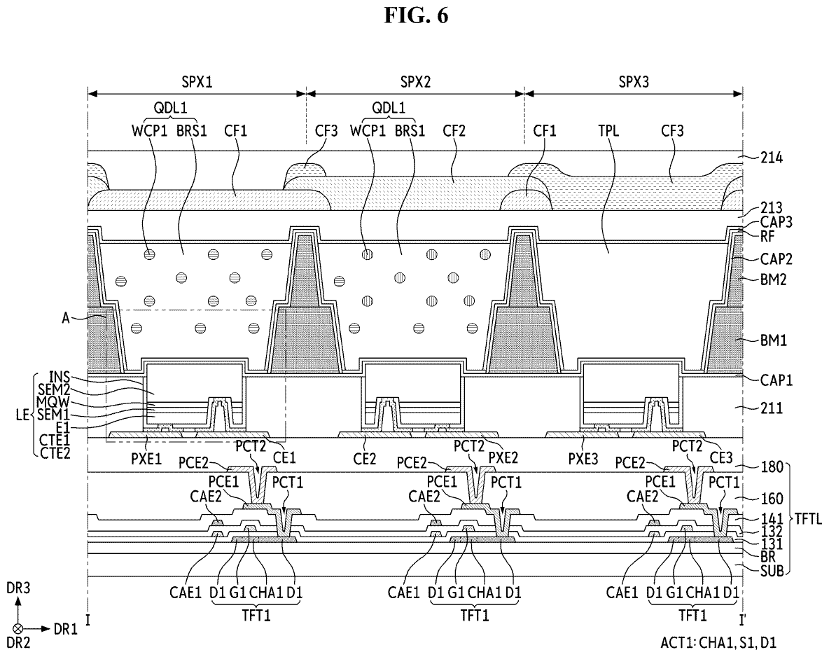

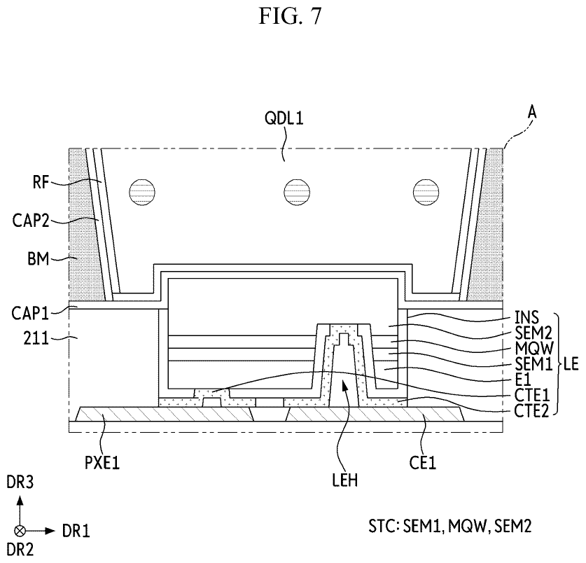

FIG. 6 is a cross-sectional view illustrating one example of a cross-section of a display panel corresponding to line I-I′ in FIG. 5. FIG. 7 is a cross-sectional view illustrating one example of area A of FIG. 6 in detail.

Referring to FIGS. 6 to 7, a substrate SUB may be formed of an insulating material such as, for example, glass, polymer resin, or the like. If the substrate SUB is formed of polymer resin, it may be a flexible substrate that may be stretched. The polymer resin may be acrylic resin, epoxy resin, phenolic resin, polyamide resin, polyimide resin, or the like.

A barrier film BR may be disposed on the substrate SUB. The barrier film BR is a film that protects the transistors of the thin film transistor layer TFTL from moisture penetrating through the substrate SUB which is vulnerable to moisture permeation. The barrier film BR may be formed of a plurality of inorganic films that are alternately stacked.

A thin film transistor TFT1 may be disposed on the barrier film BR. The thin film transistor TFT1 may be either the fourth transistor ST4 or the sixth transistor ST6 illustrated in FIG. 4. The thin film transistor TFT1 may include a first active layer ACT1 and a first gate electrode G1.

The first active layer ACT1 of the thin film transistor TFT1 may be disposed on the barrier film BR. The first active layer ACT1 of the thin film transistor TFT1 may include polycrystalline silicon, monocrystalline silicon, low-temperature polycrystalline silicon, or amorphous silicon. Alternatively, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be disposed on one side of the first channel area CHA1, and the first drain area D1 may be disposed on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate insulating film 131 may be disposed on the first channel area CHA1, the first source area S1, and the first drain area D1 of the thin film transistor TFT1.

A first gate metal layer may be disposed on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being disposed apart from each other in FIG. 6, the first gate electrode G1 and the first capacitor electrode CAE1 may be connected to each other.

A second gate insulating film 132 may be disposed on the first gate electrode G1 and the first capacitor electrode CAE1 of the thin film transistor TFT1.

A second gate metal layer may be disposed on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Since the second gate insulating film 132 has a predetermined dielectric constant, the capacitor (C1 in FIG. 4) may be formed by the first capacitor electrode CAE1, the second capacitor electrode CAE2, and the second gate insulating film 132 disposed between them.

A interlayer insulating film 141 may be disposed on the second capacitor electrode CAE2.

A first data metal layer may be disposed on the interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the interlayer insulating film 141.

A first planarization organic film 160 may be disposed on the first source connection electrode PCE1 to planarize a step caused by the thin film transistor TFT1.

A second data metal layer may be disposed on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be disposed on the second source connection electrode PCE2.

The barrier film BR, the first gate insulating film 131, the second gate insulating film 132, the third gate insulating film 133, and the interlayer insulating film 141 may be formed of an inorganic film, for example, silicon nitride (SiNₓ), silicon oxide (SiON), silicon oxide (SiOₓ), titanium oxide (TiOₓ), or aluminum oxide (AlOₓ).

The first gate metal layer, the second gate metal layer, the first data metal layer, and the second data metal layer may be formed as a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film such as, for example, an acrylic resin, an epoxy resin, a phenolic resin, a polyamide resin, a polyimide resin, or the like.

A light emitting element layer may be disposed on the second planarization organic film 180. The light emitting element layer may include pixel electrodes PXE1, PXE2, PXE3, light emitting elements LE, and a common electrode CE.

A pixel electrode layer including pixel electrodes PXE1, PXE2, and PXE3 and common electrodes CE1, CE2, and CE3 may be disposed on a second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled by the thin film transistor TFT1 may be applied to each of the pixel electrodes PXE1, PXE2, and PXE3.

The common electrodes CE1, CE2, and CE3 may be connected to a second power supply line (VSL in FIG. 4) to which a second driving voltage (VSS in FIG. 3) is applied through a common connection hole (CT4/CT5/CT6 in FIG. 5). The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one of molybdenum (Mo), aluminum (Al), chromium (Cr), gold (Au), titanium (Ti), nickel (Ni), neodymium (Nd), and copper (Cu), or alloys thereof. For example, the pixel electrode layer may be formed of copper (Cu) having low surface resistance to lower the resistance of each of the pixel electrodes PXE1, PXE2, and PXE3.

A plurality of light emitting elements LE may be disposed on each pixel electrode layer. In FIGS. 6 and 7, as an example, the light emitting elements LE are each a flip-type micro LED. The flip-type micro LED refers to an LED in which contact electrodes CTE1 and CTE2 are formed on one side (e.g., the bottom side) of the light emitting element LE. The light emitting element LE may include substantially vertical side surfaces as illustrated in FIG. 7. For example, the light emitting element LE may be patterned through vertical etching and may have a rectangular or square cross-sectional shape in which the width of the top surface and the width of the bottom surface are substantially the same. Each of the plurality of light-emitting elements LE may be formed of an inorganic material such as, for example, gallium nitride (GaN).

The shape of the light emitting element LE may vary depending on the embodiments. For example, the light emitting element LE may have an inverted tapered cross-sectional shape. For example, the light emitting element LE may have a cross-sectional shape of an inverted trapezoid where the width of the top surface is wider than the width of the bottom surface.

Each of the plurality of light emitting elements LE may be formed by growing on a semiconductor substrate such as, for example, a silicon substrate or a sapphire substrate. The plurality of light emitting elements LE may be transferred onto the pixel electrode layer of the display panel 100 directly from the semiconductor substrate or through a relay substrate. Alternatively, the plurality of light emitting elements LE may be transferred onto the pixel electrodes PXE1, PXE2, and PXE3 of the display panel 100 by an electrostatic method using an electrostatic head or a stamp method using an elastic polymer material such as, for example, PDMS or silicon as a transfer substrate.

As illustrated in FIG. 7, the light emitting element LE may include a conductive layer E1, a semiconductor stack STC, a first contact electrode CTE1, a second contact electrode CTE2, and a protective film INS. The semiconductor stack STC may include a first semiconductor layer SEM1, an active layer MQW, and a second semiconductor layer SEM2 sequentially disposed in the third direction DR3.

The conductive layer E1 may be disposed on the bottom surface of the first semiconductor layer SEM1. In FIG. 7, the conductive layer E1 is illustrated as covering the entire bottom surface of the first semiconductor layer SEM1, but embodiments of the present disclosure are not limited thereto. For example, the conductive layer E1 may be disposed on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), and copper (Cu).

The first semiconductor layer SEM1 may be disposed on the conductive layer E1. The first semiconductor layer SEM1 may be formed of a semiconductor material layer doped with a first conductive dopant such as, for example, magnesium (Mg), zinc (Zn), calcium (Ca), strontium (Sr), barium (Ba), or the like, for example, gallium nitride (GaN).

In an embodiment, the first semiconductor layer SEM1 may have a multilayer structure. For example, the first semiconductor layer SEM1 may include a P−GaN layer and a P+GaN layer. The P+GaN layer may be disposed under the P−GaN layer. The P+GaN layer may be a layer overdoped with the first conductive dopant. The P+GaN layer may be formed with a thickness of several nanometers to several tens of nanometers on the top side to help ohmic formation. The P+GaN is very useful for lowering the operating voltage by improving ohmic characteristics with the upper metal through the tunneling effect.

The active layer MQW may be disposed on the first semiconductor layer SEM1. The active layer MQW may emit light by combining electron-hole pairs according to an electrical signal applied through the first semiconductor layer SEM1 and the second semiconductor layer SEM2.

The active layer MQW may include a material having a single or multi-quantum well structure. In an example in which the active layer MQW includes a material having a multi-quantum well structure, the active layer MQW may have a structure in which a plurality of well layers and barrier layers are alternately stacked. At this time, the well layer may be formed of indium gallium nitride (InGaN), and the barrier layer may be formed of gallium nitride (GaN) or aluminum gallium nitride (AlGaN), but embodiments of the present disclosure are not limited thereto.

Alternatively, the active layer MQW may have a structure in which semiconductor materials having a high band gap energy and semiconductor materials having a low band gap energy are alternately stacked with each other, may include other Group three to five semiconductor materials according to the wavelength range of emitted light.

In an example in which the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light emitting element LE that emits the third light (light in the blue wavelength band) may be approximately 10 wt % to 20 wt %.

The second semiconductor layer SEM2 may be disposed on the first semiconductor layer SEM1. The second semiconductor layer SEM2 may be a semiconductor material layer doped with a second conductivity type dopant such as, for example, silicon (Si), germanium (Ge), tin (Sn), or the like, for example, gallium nitride (GaN).

In an embodiment, the second semiconductor layer SEM2 may have a multilayer structure. For example, the second semiconductor layer SEM2 may include an N-GaN layer and an N+GaN layer disposed on the N-GaN layer. The N+GaN layer may be a layer heavily doped with a second conductive dopant. The N+GaN layer may lower electrical resistance and improve current distribution when forming an ohmic electrode, thereby increasing the overall uniformity of light emission of the light emitting element LE.

An electron blocking layer may be disposed between the first semiconductor layer SEM1 and the active layer MQW. The electron blocking layer may be a layer to suppress or prevent too many electrons from flowing into the active layer MQW. For example, the electron blocking layer may be aluminum gallium nitride (AlGaN) or p-type aluminum gallium nitride (AlGaN) doped with p-type magnesium (Mg). The electronic blocking layer may be omitted.

A superlattice layer may be disposed between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) or p-type aluminum gallium nitride (AlGaN) doped with p-type magnesium (Mg). The superlattice layer may be omitted.

The protective film INS may be a film for protecting the bottom surface and the side surface of the light emitting element LE. The protective film INS may be disposed on the bottom surface and the side surface of the conductive layer E1 and the side surface of the semiconductor stack STC. Specifically, the protective film INS may be disposed on the bottom surface and the side surface of the conductive layer E1, the side surface of the first semiconductor layer SEM1, the side surface of the active layer MQW, and the side surface of the second semiconductor layer SEM2.

The protective film INS may be formed of an inorganic film, such as, for example, silicon nitride (SiNₓ), silicon oxide nitride (SiON), silicon oxide (SiOₓ), titanium oxide (TiOₓ), or aluminum oxide (AlOₓ).

As described herein, the plurality of light emitting elements LE are grown on a semiconductor substrate, and a portion of the protective film INS adjacent to one surface of the semiconductor stack STC where the semiconductor substrate and the semiconductor stack STC come into contact may be removed by a transfer process onto the display panel 100. Accordingly, among the side surfaces of the semiconductor stack STC, an area adjacent to the top surface of the semiconductor stack STC may be exposed by the protective film INS. For example, the protective film INS may be spaced apart from the top surface of the semiconductor stack STC in the third direction DR3. Here, the third direction DR3 may be substantially the same as the height direction (or thickness direction) of the light emitting element LE.

A hole LEH may be formed that penetrates the conductive layer E1, the first semiconductor layer SEM1, and the active layer MQW of the light emitting element LE to expose the second semiconductor layer SEM2. The hole LEH may have a rectangular planar shape, but the embodiments of the present disclosure are not limited thereto. For example, the hole LEH may have a polygonal planar shape such as, for example, a circle, an ellipse, or a square.

In some aspects, the protective film INS may be disposed on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 may be exposed without being covered by the protective film INS.

The first contact electrode CTE1 may be disposed on at least one side surface of the semiconductor stack STC, and at least one side surface and the bottom surface of the conductive layer E1. The first contact electrode CTE1 may be disposed on the bottom surface of the conductive layer E1 exposed without being covered by the protective film INS. Therefore, the first contact electrode CTE1 may be electrically connected to the conductive layer E1.

The second contact electrode CTE2 may be disposed on at least one side of the semiconductor stack STC and at least one side and the bottom surface of the conductive layer E1. At this time, the first contact electrode CTE1 may be disposed on the first side of the semiconductor stack STC and the first side of the conductive layer E1, while the second contact electrode CTE2 may be disposed on the second side of the semiconductor stack STC and the second side of the conductive layer E1.

The second contact electrode CTE2 may be disposed on the protective film INS disposed in the hole LEH and the second semiconductor layer SEM2 exposed without being covered by the protective film INS in the hole LEH. Therefore, the second contact electrode CTE2 may be electrically connected to the second semiconductor layer SEM2 in the hole LEH.

The first contact electrode CTE1 and the second contact electrode CTE2 may include one of molybdenum (Mo), aluminum (Al), chromium (Cr), gold (Au), titanium (Ti), nickel (Ni), neodymium (Nd), and copper (Cu). Specifically, the first contact electrode CTE1 and the second contact electrode CTE2 may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

The second organic film 211 may be disposed such that the second organic film 211 covers the side surfaces of the plurality of light emitting elements LE. For example, the top surfaces of each of the plurality of light emitting elements LE may be exposed without being covered by the second organic film 211. In another example, the second organic film 211 may include a plurality of stacked organic films. The second organic film 211 is a layer for flattening the steps caused by the plurality of light emitting elements LE.

The second organic film 211 may be formed from an organic film such as, for example, an acrylic resin, an epoxy resin, a phenolic resin, a polyamide resin, a polyimide resin, or the like.

A light blocking layer BM, a first light conversion layer QDL1, a second light conversion layer QDL2, and a light transmission layer TPL may be disposed on the first capping layer CAP1. The first light conversion layer QDL1, the second light conversion layer QDL2, and the light transmission layer TPL may be formed by the compartments the light blocking layer BM. Therefore, the first light conversion layer QDL1 may be disposed on the first capping layer CAP1 in the first sub-pixel SPX1, the second light conversion layer QDL2 may be disposed on the first capping layer CAP1 in the second sub-pixel SPX2, and the light transmission layer TPL may be disposed on the first capping layer CAP1 in the third sub-pixel SPX3. The light blocking layer BM may not overlap the plurality of light emitting elements LE in the third direction DR3.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may include an epoxy-based resin, an acrylic-based resin, a cado-based resin, or an imide-based resin. The first and second wavelength conversion particles WCP1 and WCP2 may be quantum dots (QD), quantum rods, fluorescent materials, or phosphorescent materials.

The light blocking layer BM may include a first light blocking layer BM1 and a second light blocking layer BM2 that are sequentially stacked. A length of the first light blocking layer BM1 in the first direction DR1 or a length of the second direction DR2 may be wider than a length of the second light blocking layer BM2 in the first direction DR1 or a length of the second direction DR2 of the second light blocking layer BM2. The first light blocking layer BM1 and the second light blocking layer BM2 may be formed of an organic film such as, for example, an acrylic resin, an epoxy resin, a phenolic resin, a polyamide resin, a polyimide resin, or the like. The first light blocking layer BM1 and the second light blocking layer BM2 may include a light blocking material to prevent light from the light emitting element LE of one sub-pixel from proceeding to the neighboring sub-pixel. For example, the first light blocking layer BM1 and the second light blocking layer BM2 may include an inorganic black pigment such as, for example, carbon black or an organic black pigment.

The second capping layer CAP2 may be disposed on the first capping layer CAP1 and the light blocking layer BM. The second capping layer CAP2 may be disposed on the side and top surfaces of the light blocking layer BM. That is, the second capping layer CAP2 may be disposed on the side of the first light blocking layer BM1 and the side and top surfaces of the second light blocking layer BM2.

The reflective film RF may be disposed between the light blocking layer BM and the first light conversion layer QDL1, between the light blocking layer BM and the second light conversion layer QDL2, and between the light blocking layer BM and the light transmission layer TPL. The reflective film RF may be disposed on a second capture layer CAP2 disposed on the side of the first light blocking layer BM1 and the side of the second light blocking layer BM2. The reflective film RF serves to reflect light traveling in the lateral direction from the first light conversion layer QDL1, the second light conversion layer QDL2, and the light transmission layer TPL.

The reflective film RF may include a highly reflective metal material such as, for example, aluminum (Al). The thickness of the reflective film RF may be approximately 0.1 nm.

Alternatively, the reflective layer RF2 may include a first layer and a second layer of M (M is an integer of 2 or more) pairs having different refractive indices to serve as Distributed Bragg Reflectors (DBR). In this case, M first layers and M second layers may be arranged alternately. The first layer and the second layer may be formed of an inorganic film, for example, silicon nitride (SiNₓ), silicon oxide (SiON), silicon oxide (SiOₓ), titanium oxide (TiOₓ), or aluminum oxide (AlOₓ).

The third capping layer CAP3 may be disposed on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, for example, silicon nitride (SiNₓ), silicon oxide (SiON), silicon oxide (SiOₓ), titanium oxide (TiOₓ), or aluminum oxide (AlOₓ). The first light conversion layer QDL1, the second capping layer CAP2, and the third capping layer CAP3 may be encapsulated by the first capture layer CAP1, the second capping layer CAP2, and the third capping layer CAP3.

A fourth organic film 213 may be disposed on the second capping layer CAP2. A plurality of color filters CF1, CF2, and CF3 may be disposed on the fourth organic film 213. The plurality of color filters CF1, CF2, and CF3 may include first color filters CF1, second color filters CF2, and third color filters CF3.

The first color filter CF1 disposed in the first sub-pixel SPX1 may transmit the first light (light in the red wavelength band) and absorb or block the third light (light in the blue wavelength band). Therefore, the first color filter CF1 may transmit the first light (light in the red wavelength band) that has been converted by the first light conversion layer QDL1 among the third light (light in the blue wavelength band) emitted from the light emitting element LE and absorb or block the third light (light in the blue wavelength band) that has not been converted by the first light conversion layer QDL1. Accordingly, the first sub-pixel SPX1 may emit the first light (light in the red wavelength band).

The second color filter CF2 disposed in the second sub-pixel SPX2 may transmit the second light (light in the green wavelength band) and absorb or block the third light (light in the blue wavelength band). Therefore, the second color filter CF2 may transmit the second light (light in the green wavelength band) that has been converted by the first light conversion layer QDL1 among the third light (light in the blue wavelength band) emitted from the light emitting element LE and absorb or block the third light (light in the blue wavelength band) that has not been converted by the first light conversion layer QDL1. Accordingly, the second sub-pixel SPX2 may emit the second light (light in the green wavelength band).

The third color filter CF3 disposed in the third sub-pixel SPX3 may transmit the third light (light in the blue wavelength band). Therefore, the third color filter CF3 may transmit the third light (light in the blue wavelength band) emitted from the light emitting element LE passing through the light transmission layer TPL. Accordingly, the third sub-pixel SPX3 may emit the third light (light in the blue wavelength band).

The first color filter CF1, the second color filter CF2, and the third color filter CF3 overlapping in the third direction DR3 may overlap with the light blocking layer BM in the third direction DR3.

A fifth organic film 214 for planarization may be disposed on the plurality of color filters CF1, CF2, and CF3.

The fourth organic film 213 and the fifth organic film 214 may be formed from an acrylic resin, an epoxy resin, a phenolic resin, a polyamide resin, a polyimide resin, or the like.

FIG. 8 is an enlarged view of a portion of a display device to illustrate an imitation pattern and an array of light emitting elements.

Referring to FIG. 8, imitation patterns SP may be disposed in a non-display area NDA, and the light emitting elements LE may be disposed in a display area DA in a plurality of columns and a plurality of rows. The plurality of imitation patterns SP-a1, SP-b1, and SP-c1 of a row of imitation patterns SP may be aligned in a first direction DR1 to correspond to the positions of the light emitting elements LE-a, LE-b, and LE-c of the first row. Expressed another way, the imitation patterns SP-a1, SP-b1, and SP-c1 may be aligned in the first direction DR1, and positions of the imitation patterns SP-a1, SP-b1, and SP-c1 may be aligned, in the second direction DR2, with the positions of the light emitting elements LE-a, LE-b, and LE-c of the first row (i.e., top row illustrated in FIG. 8) of light emitting elements.

In some aspects, the plurality of imitation patterns SP-1a, SP-1b, and SP-1c of a column of imitation patterns SP may be aligned in a second direction DR2 to correspond to the positions of the light emitting elements LE-c of the first column. Expressed another way, the imitation patterns SP-1a, SP-1b, and SP-1c may be aligned in the second direction DR2, and positions of the imitation patterns SP-1a, SP-1b, and SP-1c may be aligned, in the first direction DR1, with the positions of the light emitting elements LE-c of the first column (i.e., leftmost column illustrated in FIG. 8) of light emitting elements.

The first row of imitation patterns SP-a1, SP-b1, and SP-c1 aligned in the first direction DR1 may be disposed at the top of the display panel 100, and the second row of imitation patterns SP-1a, SP-1b, and SP-1c aligned in the second direction DR2 may be disposed at the left side of the display panel 100 but is not limited thereto. For example, the imitation patterns SP-a1, SP-b1, and SP-c1 aligned in the first direction DR1 may be disposed at the bottom of the display panel 100, and the imitation patterns SP-1a, SP-1b, and SP-1c aligned in the second direction DR2 may be disposed at the right side of the display panel 100.

The light emitting elements LE may have the same shape and size as the imitation patterns SP-a1, SP-b1, and SP-c1 disposed in the same row. For example, the light emitting element LE-a located at the first position in the first row may have the same shape and the same size as the first imitation pattern SP-a1 aligned in the first direction DR1. The light emitting element LE-b located at the second position in the first row may have the same shape and the same size as the second imitation pattern SP-b1 aligned in the first direction DR1. The light emitting element LE-c located at the third position in the first row may have the same shape and the same size as the third imitation pattern SP-c1 aligned in the first direction DR1.

The light emitting elements LE may be aligned to the imitation patterns disposed in the same row and the same column. The light emitting element LE-c located at the first position in the first row may be aligned with the first imitation pattern SP-a1 aligned in the first direction DR1 and the first imitation pattern SP-1a aligned in the second direction DR2. The light emitting element LE-b located at the second position in the first row may be aligned with the second imitation pattern SP-b1 aligned in the first direction DR1 and the first imitation pattern SP-1a aligned in the second direction DR2. The light emitting element LE-a located at the third position in the first row may be aligned with the third imitation pattern SP-c1 aligned in the first direction DR1 and the first imitation pattern SP-1a aligned in the second direction DR2.

The plurality of imitation patterns SP may be formed of a metal. For example, the plurality of imitation patterns SP may be formed in a single layer or multiple layers of any one of molybdenum (Mo), aluminum (Al), chromium (Cr), gold (Au), titanium (Ti), nickel (Ni), neodymium (Nd), and copper (Cu), or an alloy thereof.

The plurality of imitation patterns SP may be formed by patterning when forming a pixel electrode layer, or the plurality of imitation patterns SP may be formed by patterning when forming wires in a non-display area. Therefore, embodiments of the present disclosure support forming imitation patterns SP without performing a separate process.

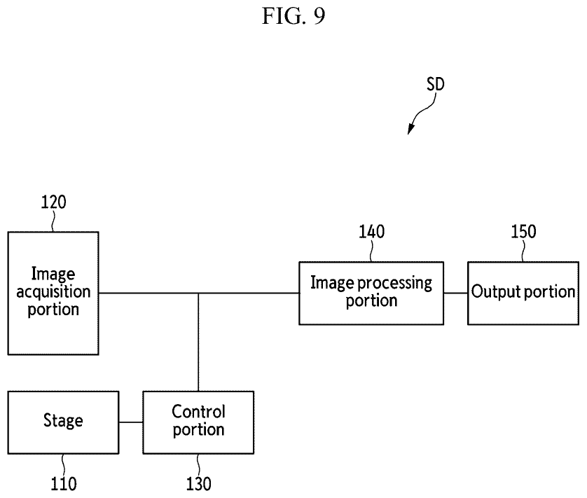

FIG. 9 is a block diagram schematically illustrating an inspection device according to an embodiment.

Referring to FIG. 9, an inspection device SD according to an embodiment is an automatic optical inspection (AOI) device that may inspect the position, width, length, or the like of holes, patterns, or the like during the manufacturing process of a display device. Further, the inspection device SD may inspect the detachment or misalignment of a light emitting element (LE in FIG. 5) based on the position of an imitation pattern (SP in FIG. 2).

The inspection device SD may include a stage 110 on which a substrate (or a display device) is mounted, an image acquisition portion 120 that captures an image of the substrate, a control portion 130 that controls the stage 110 and the image acquisition portion 120, an image processing portion 140 that inspects and determines the obtained image, and an output portion 150 that outputs the inspection result. The various portions described herein (e.g., image acquisition portion 120, control portion 130, and the like) may be, for example, implemented as a device or integrated circuitry.

The stage 110 may be supported by mounting a substrate or a display device. The stage 110 may generally be a rectangular plate, but its shape is not limited thereto. The stage 110 may be fixed or moved by the control portion 130. For example, the stage 110 may be moved up, down, left, and right according to the control signal of the control portion 130.

The image acquisition portion 120 may acquire an image by capturing an image of a substrate disposed on the stage 110. The image acquisition portion 120 may irradiate the substrate according to the signal of the control portion 130 and acquire an image from the light reflected from the substrate. In an example in which the substrate is irradiated with light in the ultraviolet ray (UV) band, the image acquisition portion 120 may acquire an image of the substrate including light emitting elements that emit excited light by light in the ultraviolet ray band. The image acquisition portion 120 may be moved up, down, left, and right according to the signal of the control portion 130 similarly to the stage 110. The image acquisition portion 120 may scan the substrate while moving to acquire an image of the substrate.

The image acquisition portion may include a light irradiation portion, a camera, and a filter.

The light irradiation portion may irradiate the substrate with light. The light irradiation portion may emit the light toward the substrate. The light irradiation portion may generate and emit visible light having a wavelength band of about 400 nm to about 740 nm. The light of the visible light band generated by the light irradiation portion may be emitted toward and irradiate a preset image capture area on the substrate. The light irradiating the substrate may be reflected from the substrate, pass through the filter portion, and be incident on the camera. The light incident on the camera may be converted into an image of the substrate.

The camera may capture light reflected from the substrate and capture an image of the substrate. The camera may capture light reflected from the substrate on which light emitting elements are disposed and capture an image of the substrate. The camera may capture light in preset photograph area units and capture an image of the imaging area. The camera may be at least one, and in the case of a plurality of cameras, each camera may capture an image of a certain area of the substrate corresponding to the installed location as a unit of the photograph area.

The camera may be a time delay integration (TDI) charge coupled device (CCD) camera. The time delay integration type CCD camera may be composed of multiple pixels, and each of the multiple pixels may output a gray value. The camera is not limited thereto and may be an infrared camera, or the like.

The light reflected from the substrate may be incident on the filter portion, and the light transmitted through the filter portion may be received by or incident the camera. The filter portion may be a ultraviolet (UV) blocking filter that transmits light in the visible light band and blocks light in the ultraviolet (UV) band. In the filter portion, light in the ultraviolet UV band is blocked and light in the visible light band is transmitted, and the transmitted light in the visible light band may be incident on the camera and converted into an image.

The control portion 130 may control the movement and operation of the stage 110 and the image acquisition portion 120. The control portion 130 may move the stage 110 and the image acquisition portion 120 up, down, left, and right. In an example in which a substrate is disposed on the stage 110, the control portion 130 moves the stage 110 and/or the image acquisition portion 120 such that the image acquisition portion 120 is aligned with the substrate. Further, the control portion 130 may control the operation of the image acquisition portion 120. For example, after the image acquisition portion 120 is aligned with the substrate, the control portion 130 may control the light irradiation portion of the image acquisition portion 120 to irradiate the substrate with light. In some aspects, the control portion 130 may control the camera to capture an image the substrate and acquire the image.

The control portion 130 may be hardware such as, for example, an electronic control unit (ECU), a micro controller unit (MCU), or the like, or software executing on the hardware, or a combination thereof.

The image processing portion 140 may process the acquired image data. According to an embodiment, the image processing portion 140 may obtain the luminance characteristic value of each pixel corresponding to each gray value by using the difference between each gray value constituting the image data and the surrounding gray values. The image processing portion 140 may be implemented as an image processor that preprocesses the image data.

In order to check whether there is a defect in the arrangement relationship of the pattern, light emitting element, or the like formed on the substrate of the display device, the image processing portion 140 may compare the image data of the copied pattern with the image data of the light emitting element from the acquired image data to determine whether there is a defect such as, for example, a detachment or misalignment of the light emitting element. Specifically, the image processing portion 140 receives the image of the imitation pattern and the light emitting elements from the image acquisition portion 120, and extracts data on the image of the imitation patterns (e.g., imitation patterns of the same row (horizontal) and the same column (vertical)) and the light emitting elements corresponding to the light emitting elements to be inspected based on the position data of the imitation patterns and the light emitting elements stored in advance. According to an embodiment, the luminance data of the imitation pattern and the light emitting elements is acquired from the image data of the imitation pattern and the light emitting elements of the same row and/or the same column. Compared with the previously stored imitation pattern and the position data of the light emitting elements, data on the similarity between the imitation pattern and the luminance data of each light emitting element in the same row is extracted, and if the similarity is less than the preset standard, the light emitting element is determined to be defective.

The output portion 150 receives data on the result of the defect inspection for the display device from the image processing portion 140 and may display the result of the defect inspection and the inspection status in real time.

Hereinafter, an inspection method for a display device capable of detecting detachment or misalignment of a light emitting element from its original position will be described with reference to other drawings. The above-mentioned position may be determined based on the imitation pattern disposed in the same column and row of the light emitting elements.

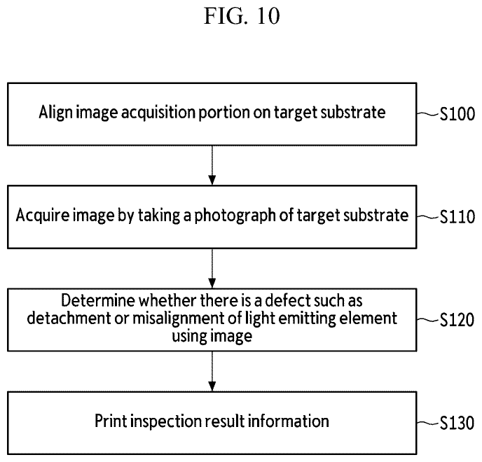

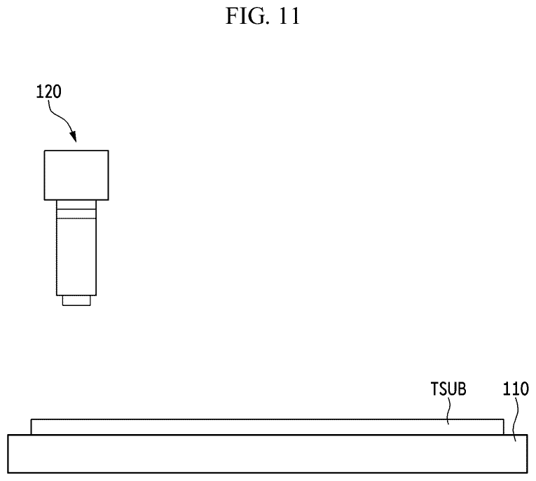

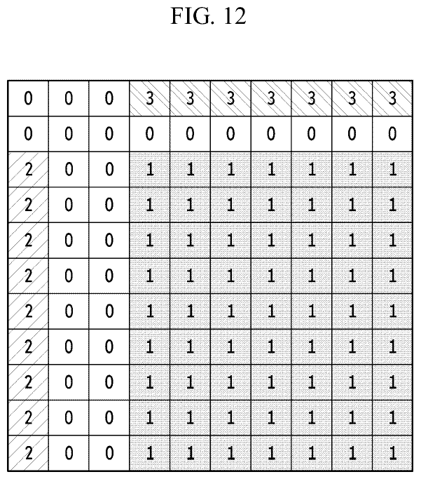

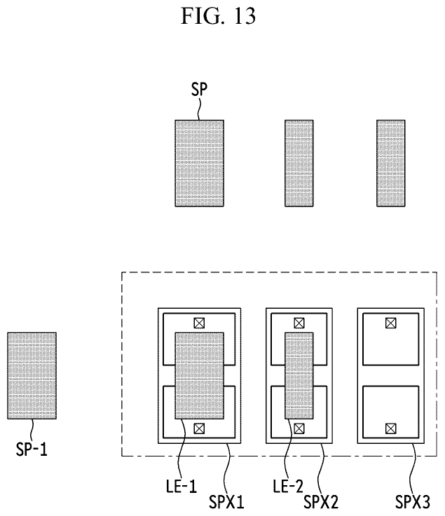

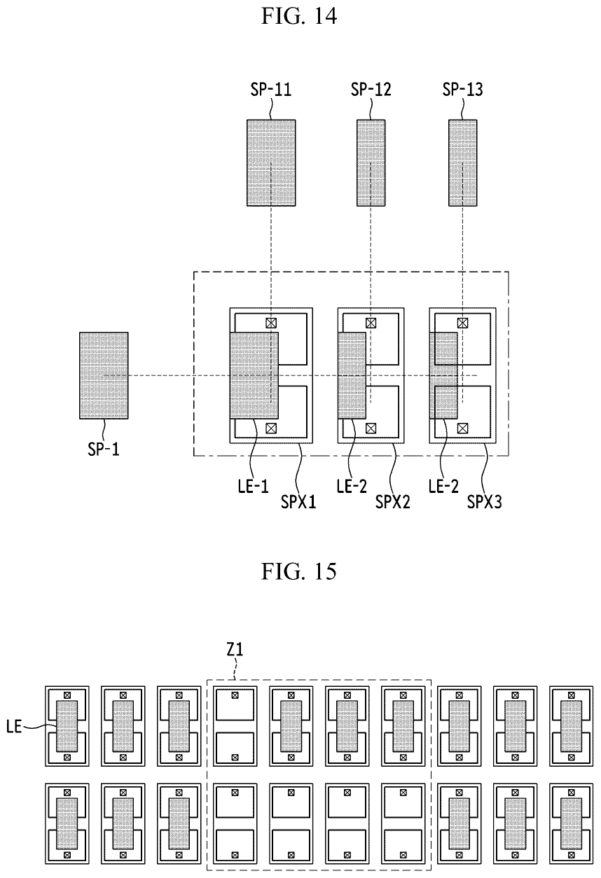

FIG. 10 is a flowchart illustrating an inspection method of a display device according to an embodiment. FIG. 11 is a schematic diagram to illustrate an inspection method of a display device according to an embodiment. FIG. 12 is an example of position data according to an embodiment. FIG. 13 and FIG. 14 are images for detecting a defect in a light emitting element by comparing one pixel to an imitation pattern. FIG. 15 is an image for illustrating defect detection in a conventional light emitting element.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added.

The inspection method of the display device according to an embodiment irradiates the display device with light emitted from the light irradiation portion, a camera captures images of an imitation pattern and the light emitting elements using the light reflected from the imitation pattern, and an image processing portion may detect array defects such as, for example, detachment and misalignment of light emitting elements based on the captured images.

Hereinafter, a method for inspecting a display device will be described in detail with reference to FIGS. 11 and 13 based on FIG. 10.

First, the method may include placing a target substrate TSUB on a stage 110 and aligning an image acquisition portion 120 with the target substrate TSUB. (S100 in FIG. 10) Referring to FIG. 11, the target substrate TSUB has light emitting elements (‘LE’ in FIG. 6) aligned along the substrate (‘SUB’ in FIG. 6) of the display area (DA in FIG. 2) and imitation patterns SP aligned along the non-display area (NDA in FIG. 2).

The image acquisition portion (‘120’in FIG. 8) and/or the stage 110 may be aligned with the target substrate TSUB according to the control signal of the control portion (‘130’ in FIG. 9).

The method may include capturing an image of the target substrate TSUB to acquire an image. (S110 in FIG. 10).

Referring to FIG. 11, the image acquisition portion 120 may capture an image of the target substrate TSUB according to the signal of the control portion 130. For example, the light irradiation portion of the image acquisition portion 120 emits light toward the target substrate TSUB (i.e., irradiating the target substrate TSUB with the emitted light) according to the signal of the control portion 130 to prepare capturing images. Then, the control portion 130 transmits a signal to the camera to capture an image of the target substrate TSUB. The camera 122 may capture the light which was emitted by the light irradiation portion and reflected from the target substrate TSUB and capture an image of the target substrate TSUB including the imitation pattern and the light emitting elements.

The method may include transmitting the acquired image to the image processing portion (‘140’ in FIG. 9).

By comparing the image data of the imitation pattern and the image data of the light emitting elements, the method may determine whether the individual light emitting elements are defective due to detachment or misalignment (S120 in FIG. 10).

The method may include analyzing the captured image based on the position data of the imitation pattern and the light emitting elements, in which the position data is stored in advance, and converting the captured image into each gray value that constitutes the image data.

Based on the position data that is stored in advance, the method may include using the difference between the gray values of the imitation pattern and the gray values of the light emitting elements in the same column and the same row to obtain the luminance characteristic value of the position corresponding to each gray value. Using this luminance characteristic value, the method may include determining the presence of a defect in the detachment and misalignment of the light emitting elements LE.

The method may include outputting the following inspection result information. (S130 in FIG. 10).

The valid defects determined by the image processing portion 140 are transmitted to the output portion (‘150’ in FIG. 9) to output the inspection result information.

As described herein, through the analysis of the image data of the light emitting elements that do not have an imitation pattern, the defects of multiple light emitting elements may be detected as a single error, and the misalignment of the entire same row may not be detected, whereas in the inspection method of the display device according to an embodiment, defects such as, for example, detachment and misalignment of each light emitting element may be detected by comparing the image data of the light emitting elements with the image data of the imitation pattern.

Referring to FIG. 12, the inspection pattern and position data of the light emitting elements in the inspection area may be stored in advance.

In FIG. 12, the area marked as ‘0’ is an area not subject to inspection, the area marked as ‘1’ indicates the position where each light emitting element is disposed, the area marked as ‘2’ indicates the position where the reference pattern for the light emitting element in the column direction (horizontal direction) is disposed, and the area marked as ‘3’ indicates the position where the reference pattern for the light emitting element in the row direction (vertical direction) is disposed.

Referring to FIG. 13, first, the method may include detecting for defects such as, for example, detachment and misalignment of the light emitting elements in the first row.

In the detected image data, the image data of the detection target light emitting elements and the imitation pattern SP-1 at position 2 in the same row are compared with the image data of the light emitting elements LE-1 and LE-2 at position ‘3’ that are the detection target. If the comparison value is less than the preset similarity (or if the difference is greater than the preset significant difference), it is determined to be a detachment defect. For example, the similarity difference between the image data of the imitation pattern SP-1 and the first sub-pixel SPX1 and the second sub-pixel SPX2 is within 10 to 50, respectively, due to the light emitting element LE, whereas the similarity difference between the image data of the imitation pattern SP-1 and the third sub-pixel SPX3 may be approximately 100 or more. In this case, it may be detected that the light emitting element is detached from the third sub-pixel SPX3.

When the image data of the imitation pattern SP-1 at the ‘2’ of the same row as the light emitting elements to be inspected and the image data of the light emitting elements LE-1, LE-2, and LE-3 at the ‘3’ of the same row as the light emitting elements to be inspected are compared, and the comparison value is greater than or equal to the preset similarity (or the difference is less than the preset significance), the image data of the imitation pattern SP-1 at position “2” of the same row as the light emitting elements to be inspected and the image data of the light emitting elements LE-1, LE-2, and LE-3 at position “3” to be inspected are checked for alignment of the same row of the imitation patterns in the image data. If the alignment of the same row matches, the light emitting elements LE-1, LE-2, and LE-3 at the ‘3’ to be inspected are compared with each of the imitation patterns SP-11, SP-12, and SP-13 in the same row. That is, the light emitting element LE-1 in row 1 is compared to the alignment with the imitation pattern SP-11 in row 1, the light emitting element LE-2 in row 2 is compared to the alignment with the imitation pattern SP-12 in row 2, and the light emitting element LE-3 in row 3 is compared to the alignment with the imitation pattern SP-13 in row 3.

In the detected image data, the image data of the imitation pattern SP-1 of the second position of the same column as the light emitting elements to be inspected are compared with the image data of the light emitting elements LE-1, LE-2, and LE-3 of the ‘3’ position to be inspected.

Through this, the misalignment of each light emitting element may be detected based on the imitation pattern. Therefore, even if all light emitting elements of the same row or column are misaligned, this may be detected.

In contrast, for example, when detecting a light emitting element detachment in a case where a conventional imitation pattern is not used, as illustrated in FIG. 15, the entire area Z1 including the area with a large difference in similarity is judged as a defective area, so it is difficult to confirm the location of the defective light emitting element, and it is also difficult to clearly confirm the number of multiple defective elements.

In some cases, when a conventional imitation pattern is not used, it is difficult to detect if all light emitting elements in the same row or column are misaligned because the alignment with neighboring light emitting elements is compared.

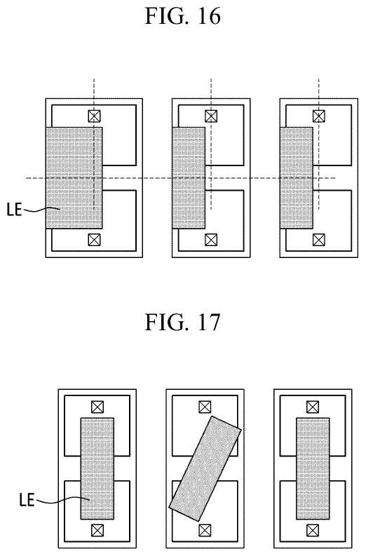

FIG. 16 to FIG. 18 are drawings to illustrate types of misalignment defects of light emitting elements that may be detected according to an embodiment of the present disclosure.

The misalignment defect of the light emitting elements may include misalignment of the entire light emitting elements and misalignment of individual light emitting elements.

Referring to FIG. 16, the defect of the entire misalignment of the light emitting elements of the same column (or the same row) may be identified. The entire misalignment of the light emitting elements of the same column (or the same row) is when the light emitting elements of the same column (or the same row) are disposed to have the same separation distance from each other but are all deviated from their normal positions by the same distance (more than a preset significance value).

According to an embodiment, since the light emitting elements of the same column are misaligned with the imitation pattern of the same column, the entire misalignment of the light emitting elements of the same column (or the same row) may be detected.

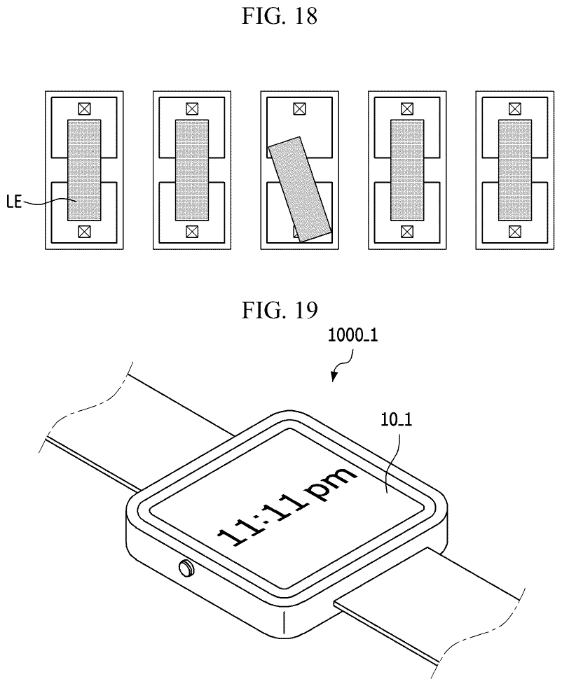

Referring to FIG. 17 and FIG. 18, the misalignment defect of one (individual light emitting element) of the light emitting elements of the same column (or the same row) may be identified.

Even if one of the light emitting elements is misaligned, the misalignment of each light emitting element may be accurately detected by judging the similarity of the light emitting elements in the same row with the imitation pattern of the same row.

Referring to FIGS. 16 to 18, according to the detection device and detection method according to an embodiment, the misalignment of each individual light emitting element may be accurately confirmed regardless of the misalignment or alignment of the neighboring light emitting elements since each light emitting element in the same row is compared with the similarity of the imitation pattern of the same row.

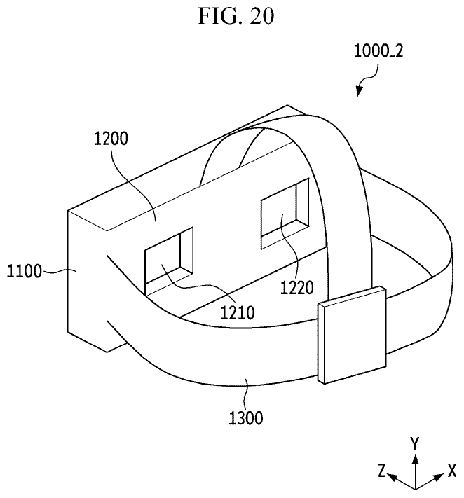

FIG. 19 is an example view of a smart watch including a display device according to one or more embodiments.

Referring to FIG. 19, a display device 10_1 according to one or more embodiments may be applied to a smart watch 1000_1 which is one of smart devices.

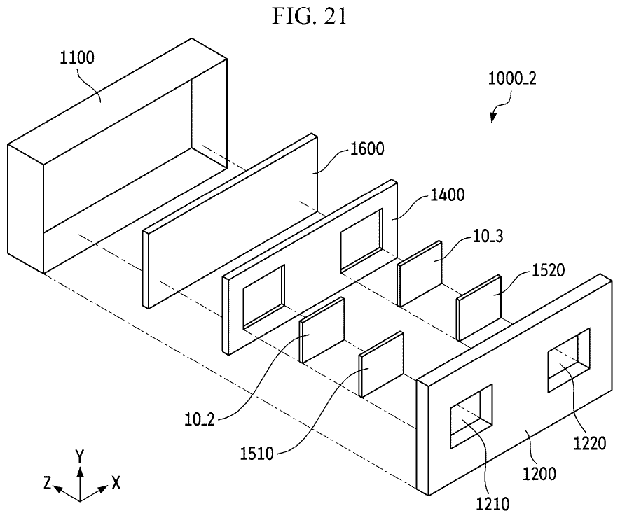

FIGS. 20 and 21 are example views of a virtual reality (VR) device including a display device according to one or more embodiments.

Referring to FIGS. 20 and 21, a head mounted display device 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to a user's left eye, and the second display device 10_3 provides an image to the user's right eye. Each of the first display device 10_2 and the second display device 10_3 is substantially the same as the display device 10 described with reference to FIGS. 1 and 2. Therefore, a description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and may be disposed between the second display device 10_3 and the control circuit board 1600. The middle frame 1400 supports and fixes the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source received from the outside into digital video data DATA and transmit the digital video data DATA to the first display device 10_2 and the second display device 10_3 through the connector.

The control circuit board 1600 may transmit the digital video data DATA corresponding to a left image optimized for a user's left eye to the first display device 10_2 and transmit the digital video data DATA corresponding to a right image optimized for the user's right eye to the second display device 10_3. Alternatively, the control circuit board 1600 may transmit the same digital video data DATA to the first display device 10_2 and the second display device 10_3.

The display device housing 1100 houses the first display device 10_2, the second display device 10_3, the middle frame 1400, the first optical member 1510, the second optical member 1520, and the control circuit board 1600. The housing cover 1200 is placed such that the housing cover 1200 covers an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are disposed separately in FIGS. 20 and 21, embodiments of the present disclosure are not limited thereto. The first eyepiece 1210 and the second eyepiece 1220 may also be combined into one.

The first eyepiece 1210 may be aligned with the first display device 10_2 and the first optical member 1510, and the second eyepiece 1220 may be aligned with the second display device 10_3 and the second optical member 1520. Therefore, a user can view an image of the first display device 10_2, which is enlarged as a virtual image by the first optical member 1510, through the first eyepiece 1210 and can view an image of the second display device 10_3, which is enlarged as a virtual image by the second optical member 1520, through the second eyepiece 1220.

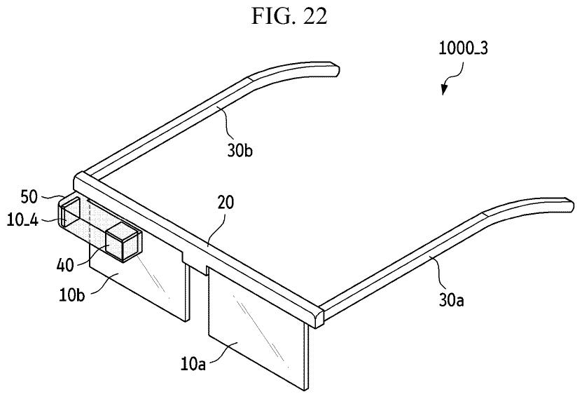

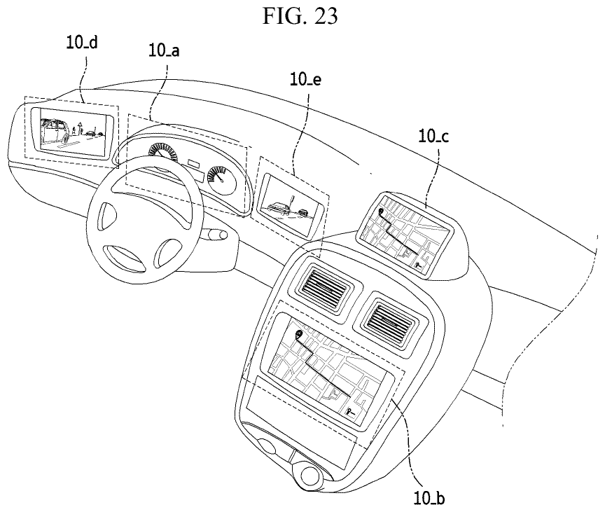

The head mounted band 1300 fixes the display device housing 1100 to a user's head such that the first eyepiece 1210 and the second eyepiece 1220 of the housing cover 1200 are kept placed on the user's left and right eyes, respectively. In an example in which the display device housing 1100 is implemented to be lightweight and small, the head mounted display device 1000_2 may include an eyeglass frame as illustrated in FIG. 22 instead of the head mounted band 1300.

In some aspects, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 22 is an example view of a VR device including a display device according to one or more embodiments. FIG. 22 illustrates a VR device 1000_3 to which a display device 10_4 according to one or more embodiments has been applied.

Referring to FIG. 22, the VR device 1000_3 according to one or more embodiments may be a device in the form of glasses. The VR device 1000_3 according to the embodiment may include the display device 10_4, a left lens 10a, a right lens 10b, a support frame 20, eyeglass frame legs 30a and 30b, a reflective member 40, and a display device housing 50.

In FIG. 22, a case where the VR device 1000_3 is a glasses-type display device including the eyeglass frame legs 30a and 30b is illustrated as an example. That is, the VR device 1000_3 according to the embodiment is not limited to the one illustrated in FIG. 22 and can be applied in various forms to various other electronic devices.

The display device housing 50 may include the display device 10_4 and the reflective member 40. An image displayed on the display device 10_4 may be reflected by the reflective member 40 and provided to a user's right eye through the right lens 10b. Accordingly, the user may view a VR image displayed on the display device 10_4 through the right eye.

Although the display device housing 50 is disposed at a right end of the support frame 20 in FIG. 22, embodiments of the present disclosure are not limited thereto. For example, the display device housing 50 may also be disposed at a left end of the support frame 20. In this case, an image displayed on the display device 10_4 may be reflected by the reflective member 40 and provided to the user's left eye through the left lens 10a. Accordingly, the user may view a VR image displayed on the display device 10_4 through the left eye. Alternatively, the display device housing 50 may be disposed at both the right end and the left end of the support frame 20. In this case, the user may view a VR image displayed on the display device 10_4 through both the left eye and the right eye.

FIG. 23 is an example view illustrating a vehicle instrument cluster and center fascia including display devices according to one or more embodiments. FIG. 23 illustrates a vehicle to which display devices 10_a through 10_e according to one or more embodiments have been applied.

Referring to FIG. 23, the display devices 10_a through 10_c according to the embodiment may be applied to an instrument cluster of the vehicle, a center fascia of the vehicle, or a center information display (CID) disposed on a dashboard of the vehicle. In some aspects, the display devices 10_d and 10_e according to the embodiment may be applied to room mirror displays that replace side mirrors of the vehicle.

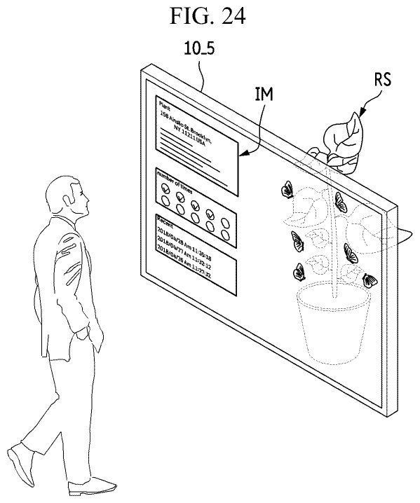

FIG. 24 is an example view of a transparent display device including a display device according to one or more embodiments.

Referring to FIG. 24, a display device 10_5 according to one or more embodiments may be applied to a transparent display device. The transparent display device may transmit light while displaying an image IM. Therefore, a user located in front of the transparent display device cannot only view the image IM displayed on the display device 10_5 but also view an object RS or the background located behind the transparent display device. In an example in which the display device 10_5 is applied to the transparent display device, a substrate of the display device 10_5 may include a light transmitting portion that can transmit light or may be formed of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. An electronic device comprising:
a display device which displays an image,
wherein the display device comprises,
a substrate comprising a display area and a non-display area;
a plurality of light emitting elements disposed in a plurality of columns and a plurality of rows in the display area;
a first plurality of imitation patterns disposed in a row direction in the non-display area, wherein positions of the first plurality of imitation patterns are respectively aligned in a column direction with light emitting elements which are comprised among the plurality of light emitting elements and disposed in a first row among the plurality of rows; and
a second plurality of imitation patterns disposed in the column direction in the non-display area, wherein positions of the second plurality of imitation patterns are respectively aligned in the row direction with light emitting elements which are comprised among the plurality of light emitting elements and disposed in a first column among the plurality of columns,
wherein for each imitation pattern of the first plurality of imitation patterns, a shape and an area of the imitation pattern are identical to a shape and an area of a light emitting element aligned with the imitation pattern in the column direction from among the light emitting elements disposed in the first row.

2. The electronic device of claim 1, wherein:
the first plurality of imitation patterns disposed in the row direction and the second plurality of imitation patterns disposed in the column direction are formed of metal, and
each of the plurality of light emitting elements is formed of an inorganic material.

3. The electronic device of claim 1, wherein:
the first plurality of imitation patterns disposed in the row direction are disposed at a top or bottom of the display area, and
the second plurality of imitation patterns disposed in the column direction are disposed at a left end or right end of the display area.

4. An inspection device comprising:
a stage on which a substrate comprising a plurality of imitation patterns and a plurality of light emitting elements is mounted;
an image acquisition portion which captures an image of the substrate;
a control portion which controls an operation of the image acquisition portion; and
an image processing portion which determines whether one or more of the plurality of light emitting elements are defective based on comparing image data of imitation patterns with image data of the plurality of light emitting elements, wherein the image data of the imitation patterns and the image data of the plurality of light emitting elements are obtained from the image acquisition portion.

5. The inspection device of claim 4, wherein:
the substrate comprises a display area and a non-display area,
the plurality of light emitting elements are disposed in a plurality of columns and a plurality of rows in the display area, and
the plurality of imitation patterns comprise:
a first plurality of imitation patterns disposed in a row direction in the non-display area, wherein positions of the first plurality of imitation patterns are respectively aligned in a column direction with light emitting elements which are comprised among the plurality of light emitting elements and disposed in a first row among the plurality of rows; and
a second plurality of imitation patterns disposed in the column direction in the non-display area, wherein positions of the second plurality of imitation patterns are respectively aligned in the row direction with light emitting elements which are comprised among the plurality of light emitting elements and disposed in a first column among the plurality of columns.

6. The inspection device of claim 5, wherein a presence of a defect comprises a detachment or misalignment of one or more light emitting elements of the plurality of light emitting elements from a respective predetermined position.

7. The inspection device of claim 6, wherein, for each light emitting element comprised among the light emitting elements, the image processing portion detects the detachment and misalignment of the light emitting element by using a difference between:
a gray value of the light emitting element;
respective gray values of a plurality of imitation patterns which are disposed in the row direction and aligned with the light emitting element in the row direction; and
respective gray values of corresponding imitation patterns of the first column.

8. The inspection device of claim 6, wherein the image processing portion extracts image data of imitation patterns corresponding to a light emitting element to be inspected based on previously stored imitation patterns and position data of the plurality of light emitting elements.

9. The inspection device of claim 5, wherein for each imitation pattern of the first plurality of imitation patterns, a shape and an area of the imitation pattern are identical to a shape and an area of a light emitting element aligned with the imitation pattern in the column direction from among the light emitting elements disposed in the first row.

10. The inspection device of claim 5, wherein:
the first plurality of imitation patterns disposed in the row direction and the second plurality of imitation patterns disposed in the column direction are formed of metal, and
each of the plurality of the light emitting elements is formed of an inorganic material.

11. The inspection device of claim 5, wherein:
the first plurality of imitation patterns disposed in the row direction are disposed at a top or bottom of the display area, and
the second plurality of imitation patterns disposed in the column direction are disposed at a left end or right end of the display area.

12. The inspection device of claim 6, further comprising an output portion that receives a defect inspection result from the image processing portion and displays the defect inspection result.

13. A method for inspecting a display device, the method comprising:
placing, on a stage, a target substrate on which a plurality of light emitting elements are formed;
aligning an image acquisition portion with the target substrate;
capturing, by the image acquisition portion, a first image of the target substrate comprising imitation patterns and the plurality of light emitting elements; and
determining whether one or more of the plurality of light emitting elements are defective based on comparing image data of the imitation patterns with image data of the plurality of light emitting elements, wherein the image data of the imitation patterns and the image data of the plurality of light emitting elements are obtained from the image acquisition portion.

14. The method of claim 13, wherein:
the target substrate comprises a display area and a non-display area,
the plurality of light emitting elements are disposed in a plurality of columns and a plurality of rows in the display area, and
the imitation patterns comprise:
a first plurality of imitation patterns disposed in a row direction in the non-display area, wherein positions of the first plurality of imitation patterns are respectively aligned in a column direction with light emitting elements which are comprised among the plurality of light emitting elements and disposed in a first row among the plurality of rows; and
a second plurality of imitation patterns disposed in the column direction in the non-display area, wherein positions of the second plurality of imitation patterns are respectively aligned in the row direction with light emitting elements which are comprised among the plurality of light emitting elements and disposed in a first column among the plurality of columns.

15. The method of claim 13, wherein determining whether the one or more of the plurality of light emitting elements are defective comprises extracting, by an image processing portion, image data of the imitation patterns corresponding to a light emitting element to be inspected based on previously stored imitation patterns and position data of the plurality of light emitting elements.

16. The method of claim 15, further comprising determining, by an image processing portion, a defect associated with the light emitting element is present based on determining that a similarity between the image data of the light emitting element to be inspected and the image data of the imitation patterns corresponding to the light emitting element is less than a preset reference value.

17. The method of claim 15, wherein the image data comprises luminance data.

18. The method of claim 16, wherein determining whether the one or more of the plurality of light emitting elements are defective comprises determining, for each light emitting element comprised among the plurality of light emitting elements, by the image processing portion, a detachment or a misalignment of the light emitting element by using a difference between:
a gray value of the light emitting element;
respective gray values of a plurality of imitation patterns which are disposed in a row direction and aligned with the light emitting element in the row direction; and
respective gray values of corresponding imitation patterns of a first column.

19. The method of claim 14, wherein:
for each imitation pattern of the first plurality of imitation patterns, a shape and an area of the imitation pattern are identical to a shape and an area of a light emitting element aligned with the imitation pattern in the column direction from among the light emitting elements disposed in the first row,
the first plurality of imitation patterns disposed in the row direction are disposed at a top or bottom of the display area, and
the second plurality of imitation patterns disposed in the column direction are disposed at a left end or right end of the display area.
